(19) United States
(12) Patent Application Publication
(10) Pub. No.: US 2024/0397790 A1
(43) Pub. Date: Nov. 28, 2024

(54) DISPLAY DEVICE AND ELECTRONIC DEVICE

(71) Applicant: SONY SEMICONDUCTOR SOLUTIONS CORPORATION, KANAGAWA (JP)

(72) Inventors: KEIICHI YAGI, KANAGAWA (JP); YOSUKE MOTOYAMA, KANAGAWA (JP); CHUGEN HAMACHI, KANAGAWA (JP); MITSURU ASANO, KANAGAWA (JP)

(21) Appl. No.: 18/695,983

(22) PCT Filed: Sep. 12, 2022
(86) PCT No.: PCT/JP2022/034002

§ 371 Date: Mar. 27, 2024

(30) Foreign Application Priority Data
Oct. 8, 2021 (JP) 2021-165990

(51) Int. Cl. H10K 59/80; H10K 59/126; H10K 59/38; H10K 59/88; H10K 102/00

(52) U.S. Cl. CPC H10K 59/8722; H10K 59/38; H10K 59/88; H10K 59/126; H10K 2102/3026

(57) ABSTRACT

Provided are a display device and an electronic device capable of suppressing entry of moisture from a boundary between a substrate and a color filter and suppressing light reflection of external light, and having an improved degree of freedom in a layout of a groove portion. A display device includes: a light emitting element substrate provided with a light emitting element; and an organic layer provided on the light emitting element substrate and having a color filter, in which there is a display area determined as a region where light generated by the light emitting element is emitted, the color filter includes a first color filter on which light generated by the light emitting element is incident, in a case where an inward-outward direction is determined along a plane direction of the display area, a non-formation portion of the organic layer is present outside the first color filter, and in a case where a direction from the organic layer toward the light emitting element substrate along a thickness direction of the organic layer is defined as a downward direction, a light shielding layer is at least partially formed immediately below the non-formation portion.

### TECHNICAL FIELD

The present disclosure relates to a display device and an electronic device.

### BACKGROUND ART

As a display device, there is known a display device including a substrate, a light emitting element such as an organic electroluminescence element (hereinafter, referred to as an organic EL element), and a color filter (on chip color filter; OCCF) formed on the substrate. In the display device, it is requested to suppress entry of moisture into the display device along an interface between the substrate and the color filter.

In response to such a request, Patent Document 1 proposes technology including a first color filter formed in a display area and a second color filter formed outside the display area, in which a groove portion is provided between the first color filter and the second color filter.

### CITATION LIST

### Patent Document

Patent Document 1: Japanese Patent Application Laid-Open No. 2016-66470

### SUMMARY OF THE INVENTION

### Problems to be Solved by the Invention

In the technology of Patent Document 1, it is required to determine a position of the groove portion in consideration of suppressing occurrence of light reflection of external light entering the substrate from the position of the groove portion. Therefore, in the technique of Patent Document 1, there is room for further improvement in terms of improving a degree of freedom in a layout of the groove portion.

The present disclosure has been made in view of the above points, and an object thereof is to provide a display device and an electronic device capable of suppressing entry of moisture from a boundary between a substrate and a color filter and suppressing light reflection of external light, and having an improved degree of freedom in a layout of a groove portion.

### Solutions to Problems

The present disclosure is, for example, (1) a display device including:
a light emitting element substrate provided with a light emitting element; and
an organic layer provided on the light emitting element substrate and having a color filter, in which
there is a display area determined as a region where light generated by the light emitting element is emitted,
the color filter includes a first color filter on which light generated by the light emitting element is incident,
in a case where an inward-outward direction is determined along a plane direction of the display area,
a non-formation portion of the organic layer is present outside the first color filter, and
in a case where a direction from the organic layer toward the light emitting element substrate along a thickness direction of the organic layer is defined as a downward direction,
a light shielding layer is at least partially formed immediately below the non-formation portion.

Furthermore, the present disclosure is (2) an electronic device in which
the display device according to (1) described above is used.

### BRIEF DESCRIPTION OF DRAWINGS

FIG. 1 is a plan view illustrating a schematic configuration of an example of a display device according to a first embodiment.

FIG. 2A is a cross-sectional view illustrating a schematic configuration of an example of the display device according to the first embodiment.

FIG. 2B is a cross-sectional view illustrating a schematic configuration of an example of the display device according to the first embodiment.

FIG. 3A is a plan view illustrating a schematic configuration of an example of a display device according to a second embodiment.

FIG. 3B is a cross-sectional view illustrating a schematic configuration of an example of the display device according to the second embodiment.

FIG. 4A is a plan view illustrating a schematic configuration of an example of a display device according to a modification of the second embodiment.

FIG. 4B is a cross-sectional view illustrating a schematic configuration of an example of a display device according to a modification of the second embodiment.

FIG. 5 is a cross-sectional view illustrating a schematic configuration of an example of a display device according to a third embodiment.

FIG. 6 is a plan view illustrating a schematic configuration of an example of a display device according to a fourth embodiment.

FIG. 7 is a cross-sectional view illustrating a schematic configuration of an example of the display device according to the fourth embodiment.

FIG. 8 is a cross-sectional view illustrating a schematic configuration of an example of a display device according to a fifth embodiment.

FIG. 9A is a plan view illustrating a schematic configuration of an example of a display device according to a sixth embodiment.

FIG. 9B is a cross-sectional view illustrating a schematic configuration of an example of the display device according to the sixth embodiment.

FIG. 10A is a plan view illustrating a schematic configuration of an example of a display device according to a seventh embodiment.

FIG. 10B is a cross-sectional view illustrating a schematic configuration of an example of the display device according to the seventh embodiment.

FIGS. 11A and 11B are views for explaining an example of an electronic device using the display device.

FIG. 12 is a view for explaining an example of an electronic device using the display device.

FIG. 13 is a view for explaining an example of an electronic device using the display device.

### MODE FOR CARRYING OUT THE INVENTION

Hereinafter, embodiments and the like according to the present disclosure will be described with reference to the drawings. Note that the description will be made in the following order. In the present specification and the drawings, configurations having substantially the same functional configuration are denoted by the same reference signs, and redundant descriptions are omitted.

Note that, the description will be given in the following order.
1. First Embodiment
2. Second Embodiment
3. Third Embodiment
4. Fourth Embodiment
5. Fifth Embodiment
6. Sixth Embodiment
7. Seventh Embodiment
8. Application Examples

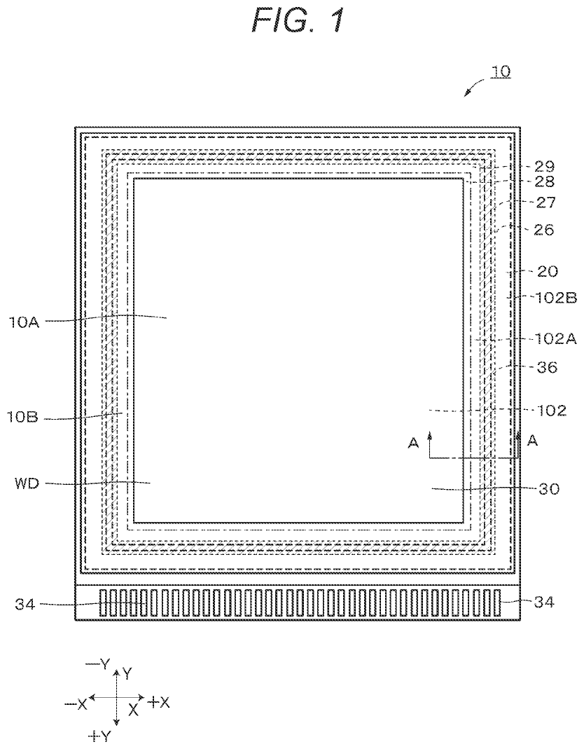

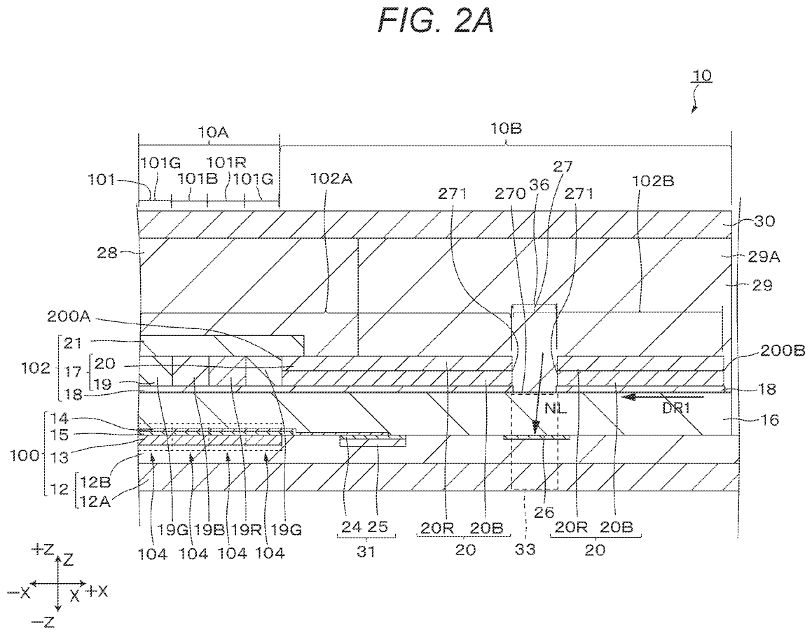

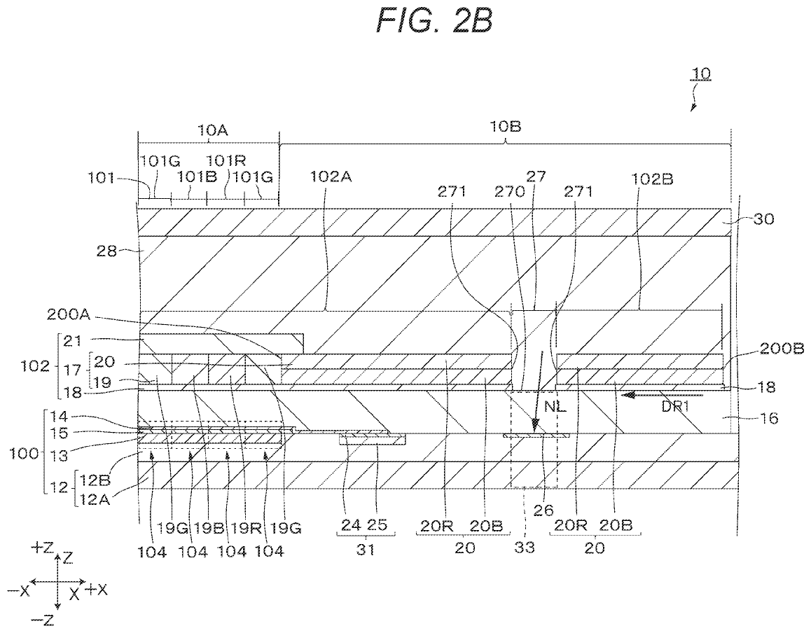

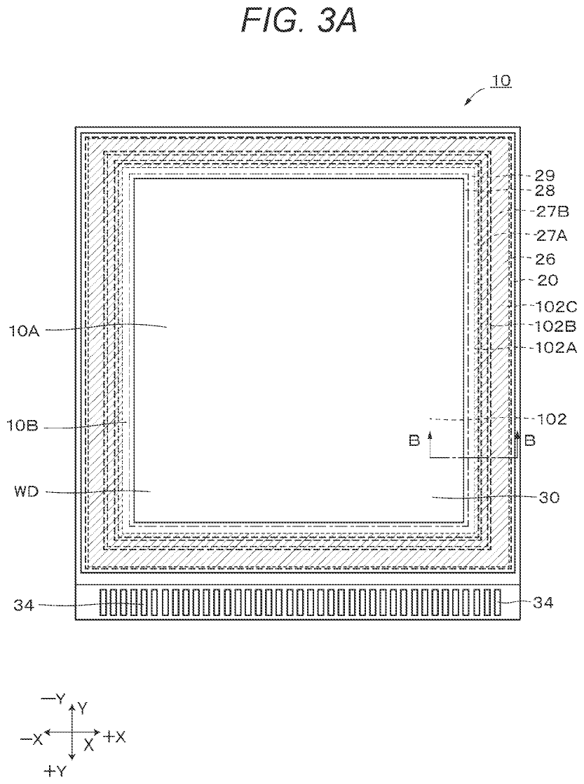

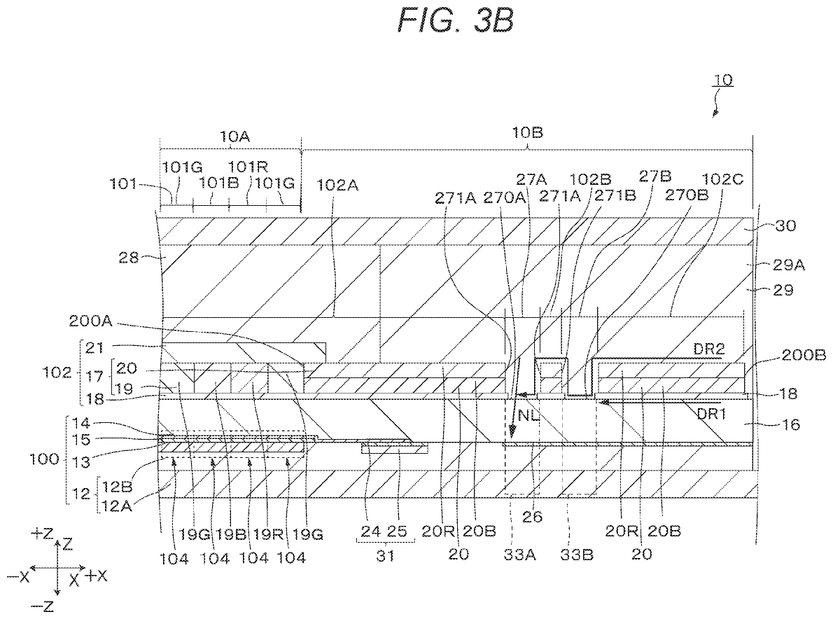

The following description is preferred specific examples of the present disclosure, and the content of the present disclosure is not limited to these embodiments and the like. Furthermore, in the following description, directions of front and back, left and right, up and down, and the like are indicated in consideration of convenience of description, but the content of the present disclosure is not limited to these directions. In examples of FIGS. 1, 2A, 2B, and the like, a Z-axis direction is defined as an up-down direction (an upper side is in a +Z direction, and a lower side is in a −Z direction), a Y-axis direction is defined as a front-back direction (a front side is in a +Y direction, and a back side is in a −Y direction), and an X-axis direction is defined as a left-right direction (a right side is in a +X direction, and a left side is in a −X direction), and the description will be made on the basis of this. This similarly applies to FIGS. 3A to 10B. A relative magnitude ratio of the size and thickness of each layer illustrated in each drawing of FIG. 1 and the like is described for convenience, and do not limit actual magnitude ratios. This similarly applies to each drawing of FIGS. 3 to 10B regarding the definition and the magnitude ratio regarding these directions.

### 1 First Embodiment

### [1-1 Configuration of Light Emitting Element Array]

An organic electroluminescence (EL) display device 10 (OLED) (hereinafter, simply referred to as a “display device 10”) as an example of a display device according to an embodiment of the present disclosure will be described below with reference to FIGS. 1 and 2A, and the like. FIG. 1 is a plan view illustrating an example of a configuration of the display device 10. FIG. 2A is a cross-sectional view for explaining a state of a longitudinal cross section taken along line A-A in FIG. 1. As illustrated in FIG. 2A, the display device 10 includes a light emitting element substrate 100 and an organic layer 102. Note that, in FIG. 1, for convenience of description, descriptions of the light emitting element substrate 100, a protective layer 16, an auxiliary electrode 31, an organic planarization layer 18, a first color filter 19, an immediately lower part 33, and the like are omitted, a boundary between a filling layer 28 and a seal portion 29 is indicated by a one dotted chain line, a groove portion 27 is indicated by a broken line thicker than a broken line indicating a light shielding layer 26, and the light shielding layer 26 is indicated by a thin broken line and hatching. This similarly applies to FIGS. 3A, 4A, 6, and 9A.

### (Display Area and Outer Area)

In the display device 10, a display area 10A and an outer area 10B are defined on a display surface WD side. The display area 10A is defined as a region where light generated from a light emitting element 104 to be described later of the light emitting element substrate 100 is emitted to the outside. The outer area 10B is determined as a region outside the display area 10A. In the example of FIG. 1, the display area 10A is formed as a rectangular region, and a region defined as a region having a rectangular ring shape outside the display area 10A is the outer area 10B. A position of an outer edge of the display area 10A is a position of an inner peripheral edge of the outer area 10B, and the display area 10A and the outer area 10B are in contact with each other at boundaries. Note that the display surface WD indicates a surface on which light generated from the light emitting element 104 is extracted to the outside in the display device 10.

Hereinafter, a case where the display device 10 is a top emission type display device will be described as an example. The top emission method indicates a method in which the light emitting element 104 is arranged on the display surface WD side from a drive substrate 12. Accordingly, in the display device 10, the drive substrate 12 is located on a back surface side of the display device 10 (a side opposite to the display surface WD), and a direction from the drive substrate 12 to the light emitting element 104 to be described later (+Z direction) is a front surface side (the display surface WD side in the display area 10A, an upper surface side) direction of the display device 10. In the display device 10, light generated from the light emitting element 104 is directed in the +Z direction and emitted to the outside. In the following description, in each layer constituting the display device 10, a surface facing the display surface WD side in a region (the display area 10A) where display is performed on the display device 10 is referred to as a first surface (upper surface), and a surface facing the back surface side of the display device 10 is referred to as a second surface (lower surface). Note that this does not prohibit a case where the display device 10 according to the present disclosure is a bottom emission type display device. The display device 10 is also applicable to a bottom emission type display device. In the bottom emission type, light generated from the light emitting element 104 is directed in the −Z direction and emitted to the outside.

### (Configuration of Sub-Pixel)

In the example of the display device 10 illustrated in FIG. 1, a plurality of pixels is formed in the display area 10A. Furthermore, one pixel is formed by a combination of a plurality of sub-pixels corresponding to a plurality of color types. In this example, three colors of red, green, and blue are determined as the plurality of color types, and three types of a sub-pixel 101R, a sub-pixel 101G, and a sub-pixel 101B are provided as the sub-pixels. The sub-pixel 101R, the sub-pixel 101G, and the sub-pixel 101B are a red sub-pixel, a green sub-pixel, and a blue sub-pixel, respectively, and display red, green, and blue, respectively. However, the example of FIG. 1 is an example, and the color types of the plurality of sub-pixels are not limited. Furthermore, wavelengths of light corresponding to respective color types of red, green, and blue can be determined as, for example, wavelengths in a range of 610 nm to 650 nm, a range of 510 nm to 590 nm, and a range of 440 nm to 480 nm, respectively. Furthermore, examples of layouts of the individual sub-pixels 101R, 101G, and 101B include a layout in which combinations of sub-pixels 101 formed in a stripe shape are arranged in a matrix. In the example of FIG. 1, the sub-pixels 101R, 101G, and 101B are two-dimensionally provided in the display area 10A. However, this does not limit a layout of the pixels and the sub-pixels in the display device 10 according to the first embodiment. The layout of the pixels and the sub-pixels may be appropriately determined, such as a rectangular layout or a delta-shaped layout.

In the following description, in a case where the sub-pixels 101R, 101G, and 101B are not particularly distinguished, a word referred to the sub-pixel 101 is used.

### (Light Emitting Element Substrate)

The light emitting element substrate 100 includes the drive substrate 12 and the light emitting element 104.

### (Drive Substrate)

As illustrated in FIG. 2A, in the drive substrate 12, an insulating layer 12B is provided on a substrate 12A, and various circuits for driving a plurality of light emitting elements 104 are provided in the insulating layer 12B. Examples of the various circuits include a drive circuit that controls driving of the light emitting elements 104 and a power supply circuit that supplies power to the plurality of light emitting elements 104 (none of which are illustrated). The various circuits are restricted from being exposed to the outside by the insulating layer 12B. Furthermore, the drive substrate 12 is provided with a plurality of contact plugs (not illustrated) for connection between the light emitting elements 104 and various circuits provided on the substrate 12A. Note that, in FIG. 2A, a description of wiring forming the various circuits is omitted for convenience of description. This similarly applies to FIGS. 2B, 3B, 4B, 5, 7, 8, 9B, and 10B.

The substrate 12A may include, for example, glass or resin having low moisture and oxygen permeability, or may include a semiconductor in which a transistor or the like is easily formed. Specifically, the substrate 12A may be a glass substrate, a semiconductor substrate, a resin substrate, or the like.

### (Insulating Layer)

The insulating layer 12B includes, for example, an organic material or an inorganic material. The organic material includes, for example, at least one of polyimide or acrylic resin. The inorganic material includes, for example, at least one of silicon oxide, silicon nitride, silicon oxynitride, or aluminum oxide.

### (Light Emitting Element)

A plurality of light emitting elements 104 is provided on the first surface of the drive substrate 12. In the example of FIG. 2A and the like, the light emitting element 104 is an organic electroluminescence element (organic EL element).

Furthermore, in this example, as the plurality of light emitting elements 104, light emitting elements in which red, green, and blue light are light emitted from the respective light emitting surfaces are provided so as to correspond to the respective sub-pixels 101R, 101G, and 101B. The plurality of light emitting elements 104 is, for example, two-dimensionally arranged in a prescribed arrangement pattern such as a matrix shape or the like.

The light emitting element 104 includes a first electrode 13, an organic light emitting layer 14, and a second electrode 15 as illustrated in a portion surrounded by a broken line on a lower side (−Z direction side) of a lens 21 described later in FIG. 2A. The first electrode 13, the organic light emitting layer 14, and the second electrode 15 are stacked in this order from the drive substrate 12 side in a direction from the second surface toward the first surface.

### (First Electrode)

A plurality of the first electrodes 13 is provided on the first surface side of the drive substrate 12. In the example of FIG. 2A, the first electrode 13 is an anode electrode.

The first electrode 13 includes at least one of a metal layer or a metal oxide layer. The first electrode 13 may include a single layer film of a metal layer or a metal oxide layer, or a laminated film of a metal layer and a metal oxide layer.

The metal layer includes, for example, at least one metal element selected from a group including chromium (Cr), gold (Au), platinum (Pt), nickel (Ni), copper (Cu), molybdenum (Mo), titanium (Ti), tantalum (Ta), aluminum (Al), magnesium (Mg), iron (Fe), tungsten (W), and silver (Ag). The metal layer may include the at least one metal element described above as a constituent element of an alloy. Specific examples of the alloy include an aluminum alloy and a silver alloy. Specific examples of the aluminum alloy include AlNd and AlCu, for example.

The metal oxide layer includes, for example, at least one of a mixture of indium oxide and tin oxide (ITO), a mixture of indium oxide and zinc oxide (IZO), or titanium oxide (TiO).

In FIG. 2A, the first electrode 13 is illustrated as an integrated layer regardless of the sub-pixel 101 for convenience of description, but more specifically, the first electrode 13 is usually electrically separated for each sub-pixel 101. That is, a plurality of the first electrodes 13 is provided on the first surface side of the drive substrate 12, and is provided for every sub-pixel 101.

Furthermore, an insulating layer is preferably formed between adjacent first electrodes 13. In the example of FIG. 2A, the insulating layer 12B is formed between adjacent first electrodes 13. However, a layer different from the insulating layer 12B may be provided as a layer having insulating properties between the adjacent first electrodes 13. In the example of FIG. 2A, the insulating layer 12B electrically separates each first electrode 13 for each light emitting element 104 (that is, for each sub-pixel 101). Furthermore, as illustrated in FIG. 2A, the first surface of the first electrode 13 (a surface opposed to the second electrode 15) is exposed from the insulating layer 12B, and is in contact with the organic light emitting layer 14 described later.

### (Organic Light Emitting Layer)

The organic light emitting layer 14 is provided between the first electrode 13 and the second electrode 15. The organic light emitting layer 14 is provided as a layer common to the sub-pixels 101. In the example of FIG. 2A, the organic light emitting layer 14 is common to the sub-pixels 101R, 101G, and 101B, and is configured to be able to emit white light. However, this does not prohibit an emission color of the organic light emitting layer 14 from being other than white, and colors including red, blue, green, and the like may be adopted. That is, the emission color of the organic light emitting layer 14 may be, for example, any one of white, red, blue, or green.

The organic light emitting layer 14 has, for example, a configuration in which a hole injection layer, a hole transport layer, a light emitting layer, and an electron transport layer are stacked in this order from the first electrodes 13 toward the second electrode 15. An electron injection layer may be provided between the electron transport layer and the second electrode 15. The electron injection layer is for increasing electron injection efficiency. Note that the configuration of the organic light emitting layer 14 is not limited thereto, and layers other than the light emitting layer are provided as necessary.

The hole injection layer is a buffer layer for enhancing hole injection efficiency into the light emitting layer and reducing leakage. The hole transport layer is for enhancing hole transport efficiency to the light emitting layer. The electron transport layer is for enhancing electron transport efficiency to the light emitting layer.

The light emitting layer generates light by electrons and holes being combined by an electric field being applied. The light emitting layer is an organic compound layer containing an organic light-emitting material.

### (Second Electrode)

In the light emitting element 104, the second electrode 15 is provided to face the first electrode 13. The second electrode 15 is provided as an electrode common to the plurality of sub-pixels 101. The second electrode 15 is a cathode electrode. The second electrode 15 is preferably a transparent electrode having transparency to light generated in the organic light emitting layer 14. The transparent electrode herein includes a transparent electrode including the transparent conductive layer and a transparent electrode including a laminated structure including the transparent conductive layer and a semi-transmissive reflective layer.

As the transparent conductive layer, a transparent conductive material having good optical transparency and a small work function is suitably used. The transparent conductive layer can include, for example, a metal oxide. Specifically, examples of a material of the transparent conductive layer can include a material including at least one of a mixture of indium oxide and tin oxide (ITO), a mixture of indium oxide and zinc oxide (IZO), or zinc oxide (ZnO).

The semi-transmissive reflective layer can include, for example, a metal layer. Specifically, examples of a material of the semi-transmissive reflective layer can include a material including at least one metal element selected from a group including magnesium (Mg), aluminum (Al), silver (Ag), gold (Au), and copper (Cu). The metal layer may include the at least one metal element described above as a constituent element of an alloy. Specific examples of the alloy include an MgAg alloy, an AgPdCu alloy, and the like.

### (Auxiliary Electrode)

In the display device 10, the auxiliary electrode 31 is provided in the outer area 10B. The auxiliary electrode 31 relays electrical connection between various circuits formed on the drive substrate 12 side and the second electrode 15.

The material of the auxiliary electrode 31 is not particularly limited as long as it is a conductive material, and for example, metal or the like can be used. As illustrated in FIG. 2A, the second electrode 15 is extended from the display area 10A to the outside (outer area 10B) and connected to the auxiliary electrode 31, so that electrical connection between the second electrode 15 and the auxiliary electrode 31 can be achieved.

In the example of FIG. 1, the auxiliary electrode 31 is formed in a ring shape so as to surround a periphery of the display area 10A in plan view of the display area 10A. However, FIG. 1 is an example, and the layout of the auxiliary electrode 31 is not limited to a ring shape.

### (Electrode Layer, Light-Shielding Conductive Layer)

A structure is not particularly limited as long as the auxiliary electrode 31 is configured to be able to connect the second electrode 15 to various circuits on the drive substrate 12 side as described above. However, in the example of FIG. 2A, the auxiliary electrode 31 has a structure in which an electrode layer 25 and a light-shielding conductive layer 24 are stacked. A material of the electrode layer 25 is not particularly limited as long as the material is a conductive material as described above for the material of the auxiliary electrode 31, and for example, metal or the like can be used. As the light-shielding conductive layer 24, a material having a light-shielding property among materials that can be used as the auxiliary electrode 31 described above can be suitably used.

### (Protective Layer)

The protective layer 16 is formed on the first surface of the second electrode 15. The protective layer 16 shields the light emitting elements 104 from the outside air, and suppress moisture infiltration into the light emitting elements 104 from the external environment. Furthermore, in a case where the semi-transmissive reflective layer of the second electrode 15 includes a metal layer, the protective layer 16 may have a function of suppressing oxidation of the metal layer.

The protective layer 16 includes an insulating material. Examples of the insulating material include inorganic materials such as SiO, SiON, AlO, and TiO. In this case, examples of the protective layer 16 include a CVD film including SiO, SiON, or the like, an ALD film including AlO, TiO, SiO, or the like, and the like. The protective layer 16 may be formed as a single layer or may be formed in a state where a plurality of layers is stacked. For example, as an example of a case where the protective layer 16 is in a state in which a plurality of layers is stacked, a case can be exemplified in which the protective layer 16 is formed in a laminated structure with an ALD film laminated on a CVD film. Note that the CVD film indicates a film formed using chemical vapor deposition. The ALD film indicates a film formed using atomic layer deposition.

### (Organic Layer)

The organic layer 102 is formed on the light emitting element substrate 100 (in the example of FIG. 2A, the first surface side). In the example of FIG. 2A, the organic layer 102 is formed on the first surface side of the light emitting element substrate 100 via the protective layer 16.

The organic layer 102 includes a color filter 17. In the example of FIG. 2A, the organic layer 102 includes the organic planarization layer 18 described next, the color filter 17, and the lens 21. Note that, in the organic layer 102, one or both of the organic planarization layer 18 and the lens 21 may be omitted, but it is preferable that the organic planarization layer 18 and the lens 21 are formed from the viewpoint of enhancing display performance of the display device 10.

### (Organic Planarization Layer)

As described above, the organic planarization layer 18 is preferably formed on the protective layer 16. The organic planarization layer 18 improves flatness of a surface on which the color filter 17 is formed. Examples of a material of the organic planarization layer 18 include an organic material such as a resin material.

### (Color Filter)

In the display device 10 illustrated in FIG. 2A, the color filter 17 is provided on the first surface side (an upper side, the +Z direction side) of the organic planarization layer 18. As the color filter 17, an on-chip color filter (OCCF) can be exemplified. In the example of FIG. 2A, the color filter 17 includes the first color filter 19 and a second color filter 20. As a material of the color filter 17, an organic material can be exemplified.

### (First Color Filter)

The first color filter 19 is preferably formed substantially in the display area 10A. Furthermore, the first color filter 19 is provided according to a color type of the sub-pixel 101. Examples of the first color filter 19 include a red color filter (red filter 19R), a green color filter (green filter 19G), and a blue color filter (blue filter 19B) in the example of FIG. 2A. The red filter 19R, the green filter 19G, and the blue filter 19B are provided in the sub-pixels 101R, 101G, and 101B, respectively. Since the first color filter 19 is provided in the display device 10, light corresponding to the color type of the sub-pixels 101R, 101G, and 101B can be effectively extracted to the outside.

### (Second Color Filter)

The second color filter 20 is formed outside the first color filter 19 provided on the outermost side. In FIG. 2A, the second color filter 20 is formed substantially in the outer area 10B. The second color filter 20 is formed so as to cover an upper side (+Z direction side) of the auxiliary electrode 31. The second color filter 20 functions as a layer having a light shielding property. In the example of FIG. 2A, the second color filter 20 has a structure in which a red color filter (red filter 20R) and a blue color filter (blue filter 20B) are laminated. The red filter 20R may be formed simultaneously with the red filter 19R by using a similar material. The blue filter 20B may be formed simultaneously with the blue filter 19B by using a similar material.

The red filter 20R can be exemplified by, for example, a filter that easily allows light of a red wavelength band among visible light to pass through, and easily absorbs light of other color wavelength bands. The blue filter 20B can be exemplified by a filter that easily allows light of a blue wavelength band among visible light to pass through, and easily absorbs light of other color wavelength bands. According to such a structure in which the red filter 20R and the blue filter 20B are laminated, light blocking can be achieved for light in wavelength bands of a wide range. Therefore, among light generated by the light emitting element 104 in the display area 10A, light traveling obliquely from the outer area 10B to the outside is substantially suppressed from passing through the second color filter 20. Thus, an effect of suppressing light leakage by the second color filter 20 is exhibited. Light traveling from the outside of the display device 10 toward the drive substrate 12 side is blocked by the second color filter 20, and entry of external light is suppressed.

As described above, the second color filter 20 has a light shielding property in a state where the red filter 20R and the blue filter 20B are laminated, and the laminated structure of the red filter 20R and the blue filter 20B functions as a light shielding filter. Note that, in the example illustrated in FIG. 2A, an innermost end 200A of the second color filter 20 is in contact with an outermost end of the first color filter 19. Note that FIG. 2A is an example, and the second color filter 20 is not limited to that having a laminated structure of filters corresponding to two color types of the red filter 20R and the blue filter 20B. The second color filter 20 may be a monochromatic filter such as a black color filter as long as a light shielding property can be exhibited. Furthermore, the second color filter 20 is not limited to the laminated structure of the filters (the red filter 20R, the blue filter 20B, and the like) described above, and may have a laminated structure of a plurality of filters individually corresponding to a plurality of different color types. For example, the second color filter may have a laminated structure (not illustrated) in which a green filter is further laminated on the red filter 20R and the blue filter 20B.

### (Non-Formation Portion)

In a case where the inward-outward direction is determined along a plane direction of the display area 10A, a non-formation portion 36 of the organic layer 102 is present outside the first color filter 19 in plan view of the display device 10. The non-formation portion 36 of the organic layer 102 is specified as a portion where formation of the organic layer 102 is avoided in plan view of the display device 10. This similarly applies to the second to seventh embodiments. Note that, in the example of FIG. 2A, the non-formation portion 36 is formed at a position outside the display area 10A. Furthermore, in the example of FIG. 2A, the groove portion 27 to be described later forms at least a part of the non-formation portion 36. The non-formation portion 36 is a portion including the groove portion 27. The non-formation portion 36 may coincide with the groove portion 27. Similarly, also in the second to sixth embodiments, the non-formation portion 36 includes the groove portion 27 or coincides with the groove portion 27. However, in a case where formation of the groove portion 27 is avoided as described later in the seventh embodiment, the non-formation portion 36 does not include the groove portion 27. Note that, in FIG. 1 and FIGS. 2B to 8, the non-formation portion 36 is omitted for convenience of description.

### (Groove Portion)

The groove portion 27 is formed at a position outside the display area 10A in plan view of the display device 10. In the first embodiment, in plan view of the display device 10, at least one groove portion 27 is formed between the innermost end 200A and an outermost end 200B of the second color filter 20. The groove portion 27 divides the organic layer 102 in the inward-outward direction. However, this does not prohibit the groove portion 27 from being formed outside of the second color filter 20 (outside of the outermost end 200B) as described later. Furthermore, omission of the structure of the groove portion 27 in the display device 10 is not prohibited. In the example of FIG. 1, the groove portion 27 is formed in a rectangular ring shape so as to surround a formation region of the first color filter 19. In this example, the organic layer 102 having the second color filter 20 is divided into a portion (first portion 102A) inside of the groove portion 27 and a portion (second portion 102B) outside of the groove portion 27. In plan view of the display device 10, a seal material 29A that forms the seal portion 29 described later is embedded in a gap (a space in the groove portion 27) between two portions (the first portion 102A and the second portion 102B). A shape of the groove portion 27 is not limited to a rectangular ring shape, and may be an annular shape, an elliptical ring shape, or the like. Furthermore, the groove portion 27 is not limited to the ring shape, and may be formed in a linear shape, for example, in accordance with a formation region of the second color filter 20.

A width of the groove portion 27 is not particularly limited, but it is preferable that a size is secured to such an extent that the function of the second color filter 20 is not impaired as much as possible, and a size is secured to such an extent that an effect of suppressing entry of moisture along an interface between the organic layer 102 and the protective layer 16 can be exhibited.

A depth of the groove portion 27 is not particularly limited as long as at least the organic layer 102 is divided in the inward-outward direction by the depth. In the example of FIG. 2A, the depth of the groove portion 27 is such a depth as to divide the second color filter 20 and the organic planarization layer 18 in the inward-outward direction, and a front surface of the protective layer 16 on the first surface side is exposed on a bottom surface 270 of the groove portion 27. That is, in this example, the bottom surface 270 of the groove portion 27 is formed by the front surface of the protective layer 16.

### (Light Shielding Layer)

In the display device 10, in a case where a direction from the organic layer 102 toward the light emitting element substrate 100 along a thickness direction of the organic layer 102 is defined as a downward direction, the light shielding layer 26 is at least partially formed immediately below the non-formation portion 36. In the display device 10, as illustrated in FIG. 2A, the light shielding layer 26 is formed at least in the immediately lower part 33. The light shielding layer 26 is a light reflection suppressing layer that suppresses reflection of light. Here, in a case where a direction (−Z direction) toward the light emitting element substrate 100 along the thickness direction (Z axis direction in the example of FIG. 2) of the organic layer 102 is defined as a downward direction, the immediately lower part 33 is defined as a portion immediately below the groove portion 27. Therefore, the immediately lower part 33 can be specified as a portion having a shape and a size corresponding to a shape and a size of the groove portion 27. The immediately lower part 33 may coincide with a portion immediately below the non-formation portion 36, or may be included in a portion immediately below the non-formation portion 36. In the example of FIG. 2A, the immediately lower part 33 is included in the portion immediately below the non-formation portion 36. The light shielding layer 26 is preferably provided on an upper end side of the immediately lower part 33 from the viewpoint of suppressing external light from entering the drive substrate 12. Note that, in FIG. 2A, the immediately lower part 33 is illustrated as the portion surrounded by a broken line, immediately below the groove portion 27. This similarly applies to FIGS. 2B, 3B, 4B, 5, 7, 8, and 9B.

The light shielding layer 26 illustrated in the example of FIGS. 1 and 2A is formed in the entire region of a formation region of the immediately lower part 33 in plan view of the display device 10, and is further formed up to a region slightly outside the immediately lower part 33 (a region deviated from the immediately lower part 33). Therefore, in this example, the light shielding layer 26 is formed in a region including the immediately lower part 33 in plan view of the display device 10. However, this is an example, and the light shielding layer 26 may not be formed up to the region outside the immediately lower part 33. That is, the light shielding layer 26 may be formed in a partial region of the immediately lower part 33. Note that, in FIG. 1, a formation region of the light shielding layer 26 is a region indicated using hatching. This similarly applies to FIGS. 3A, 4A, 6, and 9A.

Furthermore, in the example illustrated in FIG. 1, the light shielding layer 26 is formed in a ring shape so as to surround the display area 10A. Note that the light shielding layer 26 is preferably formed in a shape corresponding to the immediately lower part 33, and is not limited to the case of being formed in a ring shape.

### (Reflectance of Light Shielding Layer)

A reflectance of the light shielding layer 26 is preferably low, and specifically, is preferably lower than a reflectance of the drive substrate 12 having a structure in which a circuit is provided on the substrate 12A. Furthermore, the reflectance of the light shielding layer 26 is more preferably lower than a reflectance of a layer portion that is not wiring forming a circuit in the drive substrate 12. The layer portion that is not wiring can be exemplified by a SiO/SiN laminated film or the like. Since the light shielding layer 26 is a layer having a low reflectance (low reflection layer), a possibility that external light passes through the light shielding layer 26 and travels to the drive substrate 12 can be reduced, and a possibility that external light is reflected by the light shielding layer 26 can be reduced. The reflectance indicates a reflectance for light, and specifically indicates a reflectance for visible light.

### (Material of Light Shielding Layer)

A material of the light shielding layer 26 is not particularly limited, but is exemplified by a metal material and a compound containing a metal element. As the compound containing a metal element, a compound that is not used in application of wiring forming a circuit in the drive substrate 12 can be preferably used. As the compound containing a metal element, ceramics such as titanium nitride (TiN) can be exemplified.

### (Seal Portion)

The seal portion 29 is formed on an upper side of the organic layer 102. The seal portion 29 covers at least a part of the second color filter 20 of the organic layer 102. Furthermore, the seal portion 29 is also formed inside the groove portion 27 and is formed so as to fill the groove portion 27. The seal portion 29 is formed by a seal material. The seal material 29A is preferably a transparent adhesive layer. As a material of the seal portion 29 (a material of the seal material 29A), a resin material or the like may be used. The material of the seal portion 29 is not particularly limited, but a material having higher moisture resistance than the color filter 17 is suitably used. Note that the inside of the groove portion 27 indicates a space portion surrounded by a bottom surface and a side surface of the groove portion 27.

### (Lens)

The organic layer 102 may have the lens 21. The lens 21 is preferably formed on the first color filter 19 (on the first surface). In the example of FIG. 1, the lens 21 is provided in a layout corresponding to each sub-pixel 101. The lens 21 is preferably an on chip lends (OCL).

A shape of the lens 21 is not particularly limited. As the lens 21, a lens (so-called convex lens) formed in a convex shape having a curved surface convexly curved on the first main surface side can be exemplified. Note that, in FIG. 2, a shape of the lens 21 is not particularly defined for convenience of description. This similarly applies to FIGS. 3B, 4B, 5, 7, and 8. Since the lens 21 is provided, it is easier to adjust light generated from the light emitting element 104 to be emitted from the display area 10A, and utilization efficiency of the light can be improved.

### (Filling Layer)

In the display area 10A, as illustrated in FIG. 2A, the filling layer 28 is preferably provided so as to cover the first surface side of the lens 21. By providing the filling layer 28, the first surface side of the display area 10A can be smoothed, and the lens 21 and the light emitting element 104 can be protected from outside air and moisture. Similarly to the seal portion 29 described above, the filling layer 28 is preferably a layer having a function as a transparent adhesive layer. As a material of the filling layer 28, a resin material may be used similarly to the seal portion 29 described above.

Note that, in the example of FIG. 2A, the filling layer 28 is distinguished from the seal portion 29 described above, but this is an example, and the present disclosure is not limited thereto. The filling layer 28 may be integrally formed with the seal portion 29. This can be specifically achieved, as illustrated in the example of FIG. 2B, by forming the filling layer 28 on one surface so as to cover the entire first surface side of the organic layer 102 including a portion displayed as the seal portion 29 illustrated in FIG. 2A. In this case, the filling layer 28 also serves as the seal portion 29. Note that, in this case, the seal material 29A is formed by a material forming the filling layer 28. That is, the inside of the groove portion 27 is also filled with the material forming the filling layer 28. FIG. 2B is a cross-sectional view for explaining an example of the display device 10 according to the first embodiment.

### (Counter Substrate)

On an upper side of the filling layer 28, a counter substrate 30 is provided. As the counter substrate 30, a resin substrate, a glass substrate, or the like may be used.

### (Pad Portion)

Note that, as illustrated in the example of FIG. 1, a pad portion 34 may be formed in the outer area of the display device 10. The pad portion 34 functions as a connection terminal for electrically connecting various circuits provided on the drive substrate 12 to another control circuit substrate, an electronic element, and the like. The pad portion 34 is preferably formed by a conductive member such as metal.

### [1-2 Manufacturing Method]

In the light emitting element substrate 100, the light emitting element substrate 100 is formed by forming the light emitting element 104 on the drive substrate 12. Moreover, the protective layer 16, the organic planarization layer 18, and the color filter 17 are formed. At this time, the color filter 17 is formed by forming the first color filter 19 and the second color filter 20. The color filter 17 is an OCCF. Up to this point, a general manufacturing process of a display device may be performed. Next, the lens 21 and the groove portion 27 are formed, and the filling layer 28 is formed so as to cover the lens 21. Then, a periphery of the filling layer 28 is covered with the seal portion 29, and the counter substrate 30 is arranged. As a result, the display device 10 can be manufactured. Note that the manufacturing method illustrated here is an example, and the manufacturing method of the display device 10 is not limited thereto.

### [1-3 Functions and Effects]

In the display device 10 according to the first embodiment, as illustrated in FIG. 2, the groove portion 27 is formed, and the light shielding layer 26 is formed at least in the immediately lower part 33 of the groove portion 27. The seal material 29A forming the seal portion 29 is embedded in the groove portion 27. A depth of the groove portion 27 is a depth reaching the protective layer 16, and the seal portion 29 in the groove portion 27 is in contact with the protective layer 16. Then, usually, an adhesive force between the seal material 29A and the protective layer 16 is often stronger than an adhesive force between the color filter 17 and the protective layer 16 or an adhesive force between the organic planarization layer 18 and the protective layer 16. Furthermore, the seal material 29A is often superior in moisture resistance to the color filter 17. Therefore, even if peeling occurs at an interface between the organic layer 102 and the protective layer 16 and moisture enter along a path DR1 from the outside along the interface, the entry of moisture is suppressed since the seal portion 29 is formed to fill the groove portion 27 at a position where the moisture enters up to a position of the groove portion 27.

Normally, in a display device, wiring for forming various circuits is provided in an insulating layer. As a material for forming the wiring, a metal material or the like is used. The wiring is often provided in a pixel area or an outer area. Therefore, when external light enters the drive substrate side, the display device is required to suppress light from reaching the wiring and causing light reflection.

In the display device 10 according to the first embodiment, the light shielding layer 26 is provided in the formation region of the immediately lower part 33 of the groove portion 27 in plan view of the display device 10. Therefore, according to the first embodiment, it is possible to suppress light (in FIG. 2, indicated by an arrow NL) incident on the light emitting element substrate 100 from the outside from reaching the drive substrate 12, and light reflection by wiring constituting a circuit provided on the drive substrate 12 can be reduced. Note that, similarly, also in FIGS. 2B, 3B, 4B, 5, 7, and 8, light incident from the outside toward the light emitting element substrate 100 is indicated by an arrow NL.

Therefore, according to the first embodiment, since the light shielding layer 26 is provided, it is possible to reduce necessity of considering entry of external light at a time of positioning the groove portion 27, and it is possible to improve a degree of freedom in designing the groove portion 27.

Note that the effect of suppressing moisture entry and the effect of suppressing light reflection described above also similarly apply to a case where a material for forming the filling layer 28 is embedded in the groove portion 27 as illustrated in FIG. 2B, in the display device 10 according to the first embodiment.

### 2 Second Embodiment

### [2-1 Configuration of Display Device]

In the display device 10 according to the first embodiment, as illustrated in FIGS. 3A and 3B, a plurality of groove portions may be formed (this embodiment is referred to as a second embodiment). Furthermore, in the second embodiment, an immediately lower part is defined for each groove portion, and a plurality of immediately lower parts is formed. The second embodiment is similar to the first embodiment in configurations other than the configuration of including the plurality of groove portions and the configuration in which the immediately lower part is defined according to each groove portion, and thus a description thereof is omitted. Note that, FIGS. 3A and 3B illustrate an example of a display device according to the second embodiment. FIG. 3B is a cross-sectional view illustrating a state of a longitudinal cross section taken along line B-B in FIG. 3A.

### (Groove Portion)

In the example of FIGS. 3A and 3B, two groove portions 27A and 27B are formed, and individually separate an organic layer 102 in an inward-outward direction. In a case of this example, the organic layer 102 is divided into three portions of a first portion 102A, a second portion 102B, and a third portion 102C. The groove portion 27A is formed between the first portion 102A and the second portion 102B, and the groove portion 27B is formed between the second portion 102B and the third portion 102C. Note that, in the example illustrated in FIGS. 3A and 3B, the first portion 102A, the second portion 102B, and the third portion 102C are formed in this order in a direction from an inside of a display area 10A toward an outer area 10B.

The groove portions 27A and 27B are formed in a formation region of a second color filter 20 in the outer area 10B in plan view of a display device 10. A seal portion 29 is formed so as to fill the groove portions 27A and 27B, and a seal material 29A is embedded in the groove portions 27A and 27B. A front surface of a protective layer 16 is exposed on bottom surfaces 270A and 270B of the respective groove portions 27A and 27B, and the protective layer 16 and the seal portion 29 are in contact with each other on the individual bottom surfaces 270A and 270B.

The number of formed groove portions is not limited to the example of FIGS. 3A and 3B, and three or more groove portions may be formed.

### (Immediately Lower Part)

In the example of FIGS. 3A and 3B, as portions immediately below the respective groove portions 27A and 27B, immediately lower parts 33A and 33B are determined according to sizes and shapes of the respective groove portions 27A and 27B.

### (Light Shielding Layer)

As illustrated in FIG. 3B, a light shielding layer 26 is provided so as to traverse the immediately lower part 33A and the immediately lower part 33B. Therefore, as illustrated in FIG. 3A, the light shielding layer 26 is formed in a region including a formation region of the immediately lower part 33A and the immediately lower part 33B in plan view of the display device 10. Note that the light shielding layer 26 illustrated in FIG. 3B extends to an outer end of the outer area 10B, but this is an example, and may be formed in a region inside of the outer end of the outer area 10B.

### [2-2 Functions and Effects]

According to the display device 10 according to the second embodiment, it is possible to achieve functions and effects similar to those of the first embodiment. Furthermore, in the display device 10 according to the second embodiment, the plurality of groove portions 27A and 27B is formed. Therefore, as illustrated in FIG. 3B, even when moisture enters the display area 10A from the outer area 10B along the path DR1 along an interface between the organic layer 102 and the protective layer 16, there is a plurality of contact points between the seal portion 29 and the protective layer 16 in accordance with the number of formed groove portions, so that entry of moisture toward the display area 10A can be further suppressed. Furthermore, in the second embodiment, since the plurality of groove portions 27A and 27B is formed, a total contact area between the seal portion 29 and the organic layer 102 can be increased. Therefore, even in a case where moisture enters along a path DR2 along an interface between the seal portion 29 and the organic layer 102, a moving distance of the moisture necessary for the moisture to reach the display area 10A can be extended, and it is possible to increase a time constant of entry of moisture from the outside toward the light emitting element 104 in the display area 10A.

In the display device 10 according to the second embodiment, the light shielding layer 26 is formed in the formation region of the immediately lower parts 33A and 33B. Therefore, even if external light (indicated by an arrow NL in FIG. 3B) travels toward the light emitting element substrate 100 through either the groove portion 27A or the groove portion 27B, reflection of external light is suppressed by the light shielding layer 26, and occurrence of light reflection by wiring on a drive substrate 12 side can be suppressed.

Therefore, according to the second embodiment, since the light shielding layer 26 is formed, it is possible to reduce necessity of considering reflection of external light at a time of positioning the groove portion 27A and the groove portion 27B, and it is possible to improve a degree of freedom in designing the groove portion 27A and the groove portion 27B.

### [2-3 Modification]

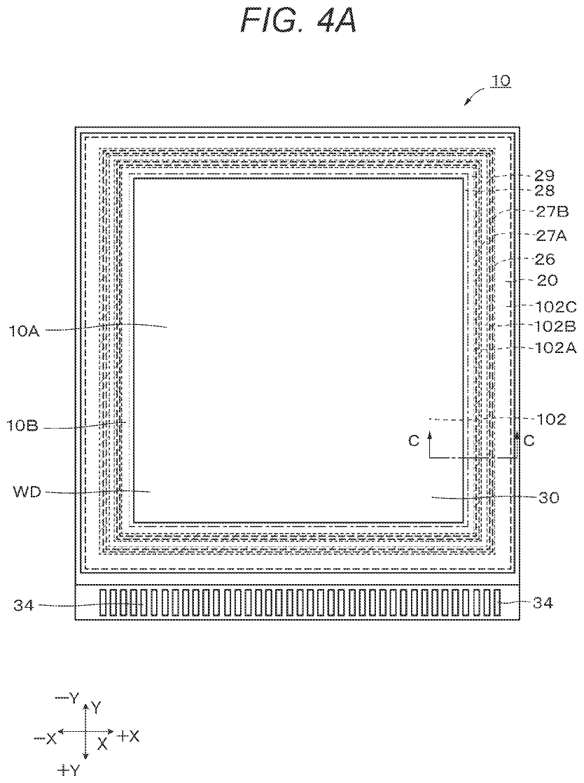

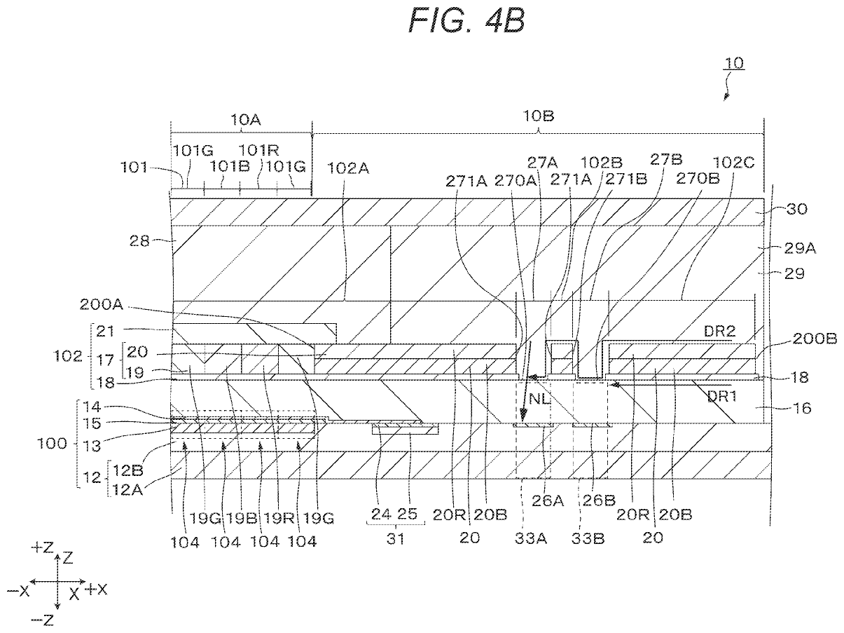

In the second embodiment, as illustrated in FIGS. 4A and 4B, light shielding layers 26A and 26B may be individually formed at positions of the respective immediately lower parts 33A and 33B (this embodiment is referred to as a modification of the second embodiment). FIGS. 4A and 4B are a plan view and a cross-sectional view for explaining an example of a display device according to the modification of the second embodiment. FIG. 4B is a cross-sectional view for explaining a state of a longitudinal cross section taken along line C-C in FIG. 4A.

Note that, in the second embodiment, in a case where three or more groove portions are formed and thus three or more immediately lower parts are defined, a light shielding layer may be individually formed at a position of each immediately lower part, or a light shielding layer may be formed as the light shielding layer 26 so as to traverse at least two immediately lower parts.

### (Light Shielding Layer)

In the examples of FIGS. 4A and 4B, the light shielding layers 26A and 26B are formed in formation regions of the respective immediately lower parts 33A and 33B, in plan view of the display device 10. The light shielding layer 26A includes the formation region of the immediately lower part 33A, and is formed up to a position slightly outside the immediately lower part 33A. The light shielding layer 26B includes the formation region of the immediately lower part 33B, and is formed up to a position slightly outside the immediately lower part 33B. However, this is an example, and similarly to the first embodiment, the light shielding layers 26A and 26B may be provided in a part of the immediately lower parts 33A and 33B, respectively. Materials of the light shielding layers 26A and 26B may be similar to that of the first embodiment. Materials of the light shielding layers 26A and 26B may be mutually the same or different from each other.

### 3 Third Embodiment

### [3-1 Configuration of Display Device]

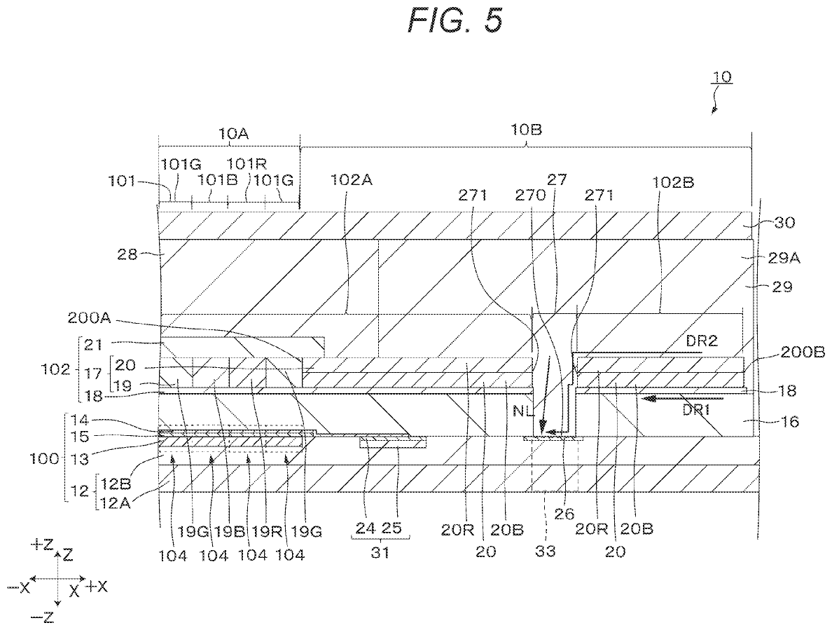

In a display device 10 according to a third embodiment, as illustrated in FIG. 5, a depth of a groove portion 27 is deeper than that of the display device 10 according to the first embodiment. The third embodiment may be configured similarly to the first embodiment in configurations other than the configuration in which the depth of the groove portion 27 is deeper than that in the first embodiment. In the description of the display device 10 according to the third embodiment, a description of configurations similar to those of the first embodiment will be omitted. FIG. 5 is a cross-sectional view illustrating an example of the display device according to the third embodiment.

### (Groove Portion)

In the display device 10 according to the third embodiment, a bottom surface 270 of the groove portion 27 is located below an organic layer 102, that is, on a drive substrate 12 side (a lower side, the −Z direction side) with respect to a front surface of a protective layer 16. In the example of FIG. 5, the bottom surface 270 of the groove portion 27 is located on a second surface side of the protective layer 16. However, this does not prohibit the bottom surface 270 of the groove portion 27 from being located inside the protective layer 16. Similarly to the first embodiment, a seal portion 29 fills the groove portion 27. Therefore, the seal portion 29 is in contact with the protective layer 16 for a part of a side surface 271 of the groove portion 27.

### [3-2 Functions and Effects]

According to the display device 10 according to a modification of the third embodiment, the seal portion 29 and the protective layer 16 come into contact with each other not only on the bottom surface 270 of the groove portion 27 but also on the side surface 271. Therefore, even when moisture enters from an outer area 10B toward a display area 10A along a path DR1 along an interface between the organic layer 102 and the protective layer 16, entry of moisture toward the display area 10A can be further suppressed. Furthermore, in a case where moisture enters along a path DR2 along an interface between the seal portion 29 and the organic layer 102, since the groove portion 27 is formed deep not only in the organic layer 102 but also in a layer on the drive substrate 12 side such as the protective layer 16, a moving distance of the moisture necessary for the moisture to reach the display area 10A can be increased (a distance of the path DR2 can be increased), and it is possible to increase a time constant of entry of moisture from the outside toward the light emitting element 104 in the display area 10A.

Furthermore, a light shielding layer 26 is formed in a formation region of the immediately lower part 33. Therefore, similarly to the first embodiment, it is possible to reduce the necessity of considering entry of external light (in FIG. 5, indicated by an arrow NL) at a time of positioning the groove portion 27, and it is possible to improve a degree of freedom in designing the groove portion 27.

### 4 Fourth Embodiment

### [4-1 Configuration of Display Device]

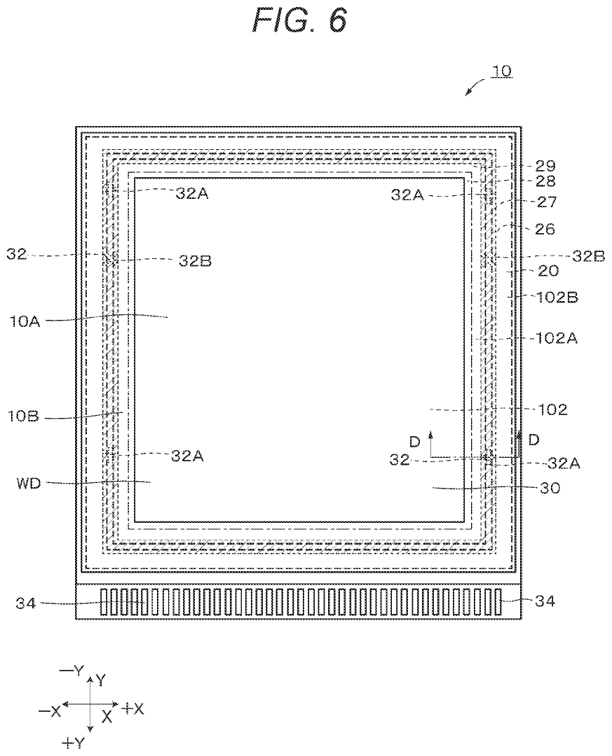

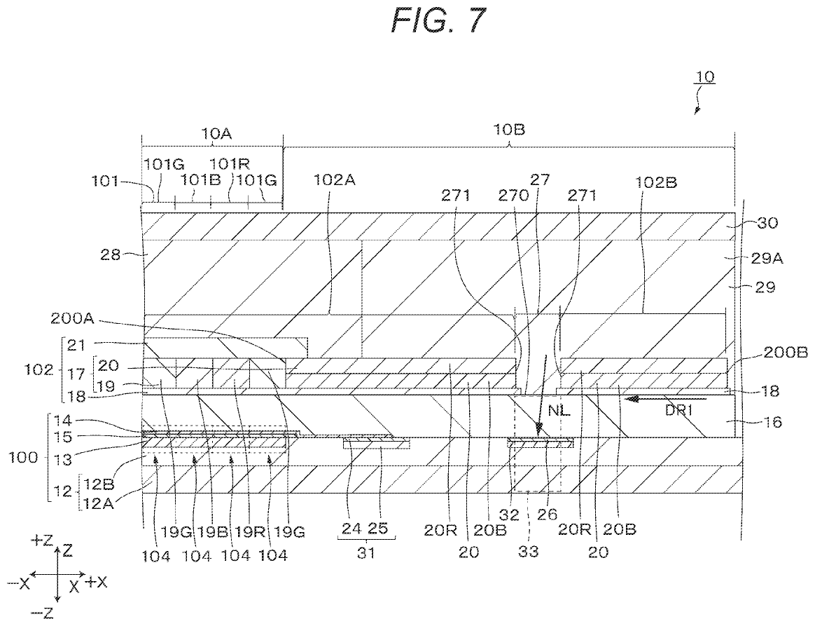

In a display device 10 according to a fourth embodiment, as illustrated in FIGS. 6 and 7, an alignment mark 32 may be provided in an immediately lower part 33, in plan view of the display device 10. In the fourth embodiment, configurations other than the configuration in which the alignment mark 32 is provided in the immediately lower part 33 may be configured similarly to the first embodiment. In the description of the display device 10 according to the fourth embodiment, a description of configurations similar to those of the first embodiment will be omitted. FIGS. 6 and 7 are a plan view and a cross-sectional view for explaining an example of a display device according to a modification of the fourth embodiment. FIG. 7 is a cross-sectional view for explaining a state of a longitudinal cross section taken along line D-D in FIG. 6.

### (Alignment Mark)

In the example of the display device 10 illustrated in FIG. 6, the immediately lower part 33 is defined in a rectangular shape in accordance with a groove portion 27 in plan view of the display device 10, and a cross-shaped mark (first mark 32A) is formed as the alignment mark 32 at four positions near four corners of the groove portion 27. Furthermore, a mark (second mark 32B) obtained by rotating the first mark by about 450 is formed on each of a pair of opposing sides (two sides) of the groove portion. The alignment mark 32 can be used as a marker for positioning or the like in a manufacturing process of the display device 10. The example of FIG. 6 is an example, and a position and a shape of the alignment mark 32 are not limited to the example of FIG. 6. Note that, in FIG. 6, the alignment mark 32 is a portion indicated by a broken line and hatching of a pattern different from hatching indicating a region of the groove portion 27.

As illustrated in the example of FIG. 7, positions of the alignment marks 32 (the first mark 32A and the second mark 32B) in an up-down direction with respect to a light shielding layer 26 are not limited. Any of the alignment marks 32 may be formed immediately below the light shielding layer 26. A material of the alignment mark 32 is not particularly limited, and can be exemplified by a metal and a compound containing a metal element, for example. As the compound containing a metal element, ceramics such as titanium nitride can be exemplified.

### [4-2 Functions and Effects]

According to the display device 10 according to the fourth embodiment, since the groove portion 27 and the light shielding layer 26 are provided, effects similar to those of the first embodiment can be obtained. Furthermore, according to the display device 10 according to the fourth embodiment, since the alignment mark 32 is arranged in the immediately lower part 33, in plan view of the display device 10, the immediately lower part 33 can be used not only as a formation region of the light shielding layer 26 but also as an arrangement region of the alignment mark 32. As a result, it is possible to reduce necessity of separately providing a region for providing the alignment mark 32, and to improve space efficiency.

### 5 Fifth Embodiment

### [5-1 Configuration of Display Device]

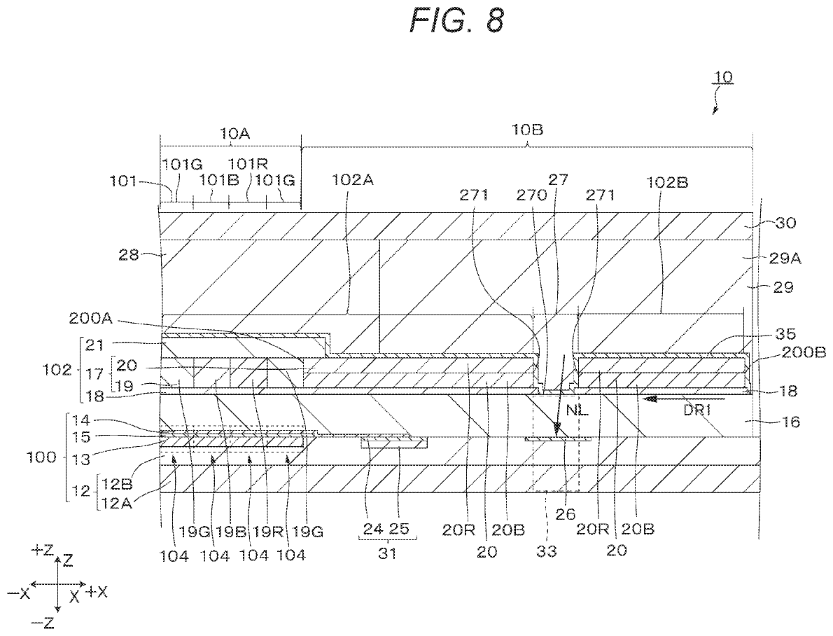

In a display device 10 according to a fifth embodiment, as illustrated in FIG. 8, an inorganic layer 35 may be further formed on a first surface of an organic layer 102 and an inner surface of a groove portion 27. FIG. 8 is a cross-sectional view illustrating an example of the display device 10 according to the fifth embodiment. In the fifth embodiment, configurations other than the configuration in which the inorganic layer 35 is provided may be configured similarly to the first embodiment. In the description of the display device 10 according to the fifth embodiment, a description of configurations similar to those of the first embodiment will be omitted. Note that the inner surface of the groove portion 27 indicates a surface obtained by combining a side surface 271 and a bottom surface 270 of the groove portion 27.

### (Inorganic Layer)

The inorganic layer 35 is formed between the organic layer 102 and a seal portion 29 and between the groove portion 27 and the seal portion 29 (seal material 29A). Furthermore, the inorganic layer 35 is also provided between the organic layer 102 and a filling layer 28. In the example of FIG. 8, the inorganic layer 35 is formed so as to cover the first surface side of the organic layer 102, and is formed on one surface so as to also cover the inner surface of the groove portion 27.

The inorganic layer 35 is formed by an inorganic material. The inorganic material is not particularly limited, and an inorganic material and the like that can be used as a protective layer 16 can be exemplified. The inorganic layer 35 can protect a light emitting element 104 similarly to the protective layer 16. Therefore, in a case where the protective layer 16 is used as a first protective layer, the inorganic layer 35 can be made function as a second protective layer. Furthermore, the inorganic layer 35 can protect the organic layer 102 by suppressing exposure of the organic layer 102.

### (Groove Portion)

As described above, the side surface 271 and the bottom surface 270 forming the inner surface of the groove portion 27 are covered with the inorganic layer 35. Therefore, the seal material 29A is embedded on a formation surface of the inorganic layer 35 in the groove portion 27. Therefore, in the groove portion 27, the seal portion 29 faces the protective layer 16 via the inorganic layer 35.

### [5-2 Functions and Effects]

In the display device 10 according to the fifth embodiment, the inorganic layer 35 and the protective layer 16 are in contact with each other at the bottom surface 270 of the groove portion 27. Therefore, even if peeling occurs at an interface between the organic layer 102 and the protective layer 16 and moisture enters along a path DR1 from the outside along the interface, the entry of moisture is suppressed at a position where the entry of moisture has progressed up to a position of the groove portion 27.

Then, in the display device 10 according to the fifth embodiment, a light shielding layer 26 is provided similarly to the first embodiment. Therefore, according to the first embodiment, by providing the light shielding layer 26, it is possible to reduce the necessity of considering entry of external light (an arrow NL in FIG. 8) at a time of positioning the groove portion 27, and it is possible to improve a degree of freedom in designing the groove portion 27.

### 6 Sixth Embodiment

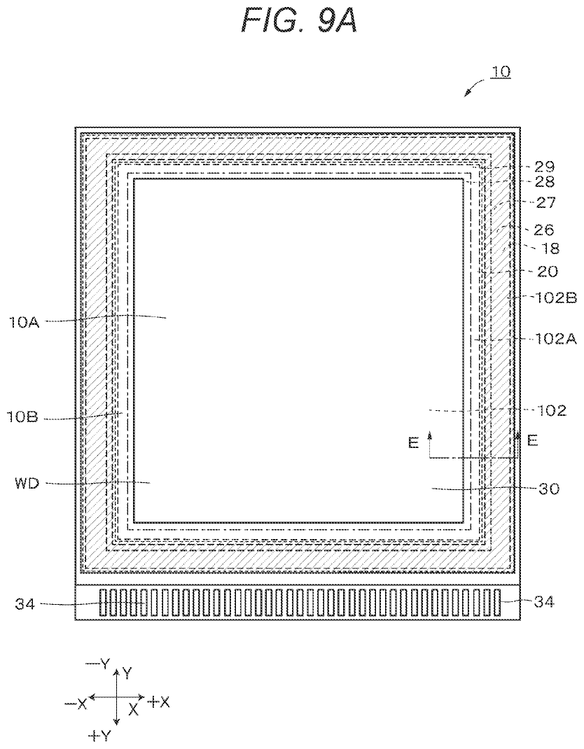

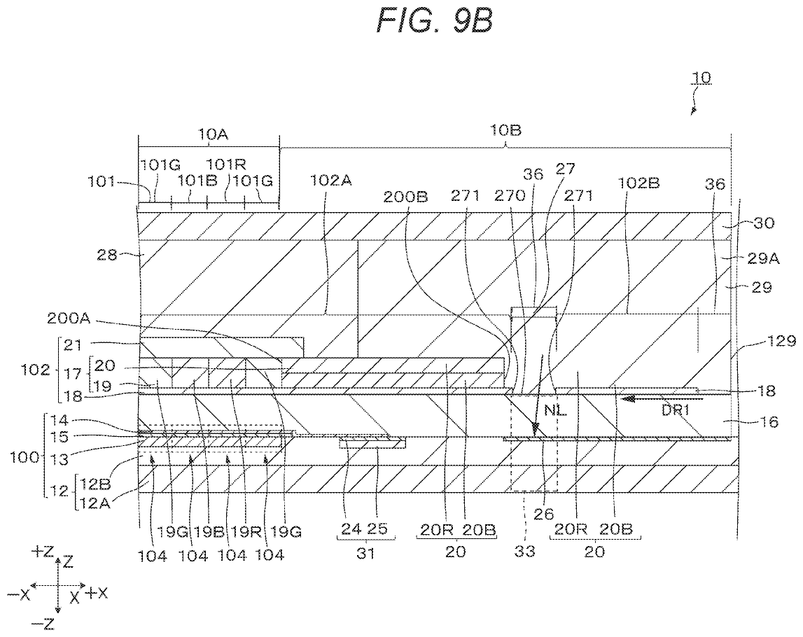

In a display device 10 according to a sixth embodiment, as illustrated in FIGS. 9A and 9B, in plan view of the display device 10, an organic layer 102 may have a configuration in which an organic planarization layer 18 extends outside of a color filter 17, and a groove portion 27 may be formed outside of the color filter 17. FIGS. 9A and 9B are a plan view and a cross-sectional view for explaining an example of the display device according to the sixth embodiment. FIG. 9B is a cross-sectional view illustrating a state of a longitudinal cross section taken along line E-E in FIG. 9A. The display device 10 according to the sixth embodiment may be configured similarly to the first embodiment in configurations other than the configurations of the organic layer 102 and the groove portion 27 described above. In the examples of FIGS. 9A and 9B, a first color filter 19 and a second color filter 20 are formed for the color filter 17, the organic planarization layer 18 of the organic layer 102 extends to the outside of the second color filter 20 (outside of an outermost end 200B), and the groove portion 27 is formed outside of the second color filter 20. Also in the sixth embodiment, similarly to other embodiments, a light shielding layer 26 is formed in a formation region of each of immediately lower parts 33 in plan view of the display device 10. In the example of FIGS. 9A and 9B, the light shielding layer 26 includes the formation region of the immediately lower part 33, and is formed from slightly inside the immediately lower part 33 up to a position of an outer peripheral edge portion 129 of a seal portion 29. Note that, in the description of the display device 10 according to the sixth embodiment, a description of configurations similar to those of the first embodiment will be omitted.

Furthermore, in the sixth embodiment, the second color filter 20 may be omitted. In this case, the organic planarization layer 18 of the organic layer 102 extends outside of the first color filter 19, and the groove portion 27 is formed outside of the first color filter 19. Note that, the point that the second color filter 20 may be omitted similarly applies to the seventh embodiment described next.

Also in the sixth embodiment, similarly to the first embodiment, it is possible to obtain effects of suppressing entry of moisture along a path DR1 and reducing the necessity of considering entry of external light (an arrow NL in FIG. 9B) at a time of positioning the groove portion 27.

### 7. Seventh Embodiment

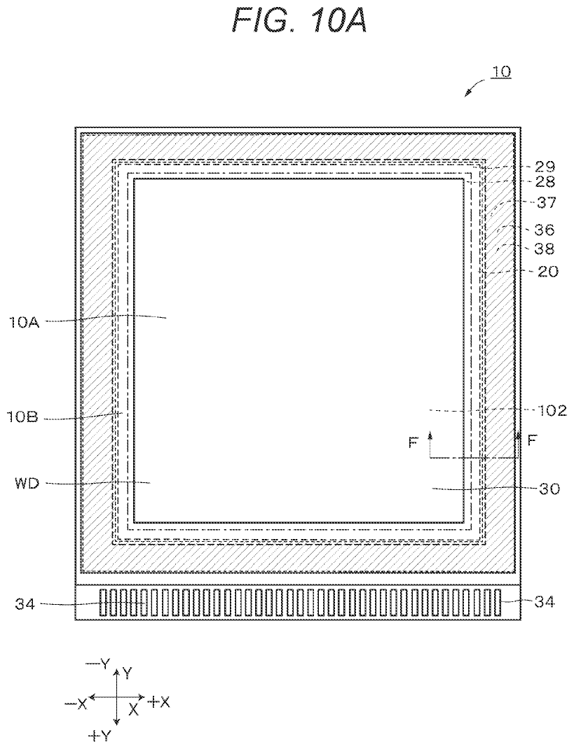

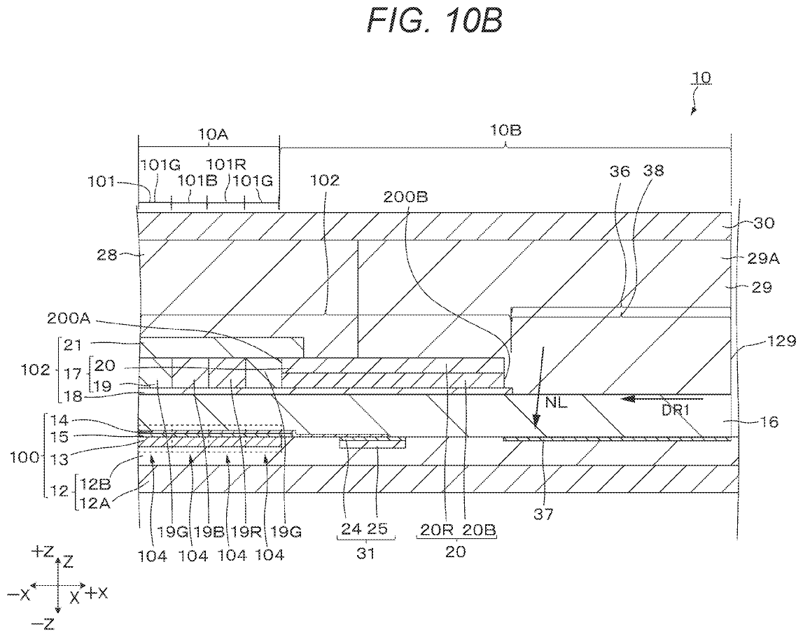

In a display device 10 according to a seventh embodiment, as illustrated in FIGS. 10A and 10B, in plan view of the display device 10, an outer peripheral edge portion of an organic layer 102 is located inside of an outer peripheral edge portion of a protective layer 16, and a seal portion 29 is formed outside of the outer peripheral edge portion of the organic layer 102. A portion 38 at which the seal portion 29 and the protective layer 16 face each other without interposing the organic layer 102 is formed as a non-formation portion 36. Then, in plan view of the display device 10, a light shielding layer 37 is formed at the portion immediately below the non-formation portion 36 or so as to include the non-formation portion 36. The light shielding layer 37 may be formed similarly to the light shielding layer 26 described in the first embodiment. Furthermore, in the display device 10 according to the seventh embodiment illustrated in the examples of FIGS. 10A and 10B, the groove portion 27 and the light shielding layer 26 described in the first embodiment and the like are omitted, and the non-formation portion 36 does not include the groove portion 27. In the display device 10 according to the seventh embodiment, configurations other than the light shielding layer 37, the groove portion 27, and the light shielding layer 26 described above may be configured similarly to the first embodiment. However, omission of the groove portion 27 and the light shielding layer 26 in the examples of FIGS. 10A and 10B does not prohibit further formation of the groove portion 27 and the light shielding layer 26 described in the first embodiment and the like in the seventh embodiment. FIGS. 10A and 10B are a plan view and a cross-sectional view for explaining an example of the display device according to the seventh embodiment. FIG. 10B is a cross-sectional view for explaining a state of a longitudinal cross section taken along line F-F in FIG. 10A. Note that, in the description of the display device 10 according to the seventh embodiment, a description of configurations similar to those of the first embodiment will be omitted. Furthermore, in FIG. 10A, the light shielding layer 37 is indicated by a thin broken line and hatching.

Also in the seventh embodiment, similarly to the first embodiment, the effect of suppressing entry of moisture along a path DR1 can be obtained. Furthermore, it is possible to reduce the necessity of considering entry of external light (an arrow NL in FIG. 10B) at a time of positioning the portion 38 that is to be the non-formation portion 36.

### 6 Application Example

The display device according to the present disclosure may be provided in various electronic devices. For example, the display device (display device 10) according to the above-described embodiment (any one of the first to seventh embodiments) may be provided in various electronic devices. Especially, the display device according to the above-described embodiment is preferably provided in an electronic viewfinder of a video camera or a single-lens reflex camera, a head mounted display, or the like in which high resolution is required, used for enlarging near the eyes.

### Specific Example 1

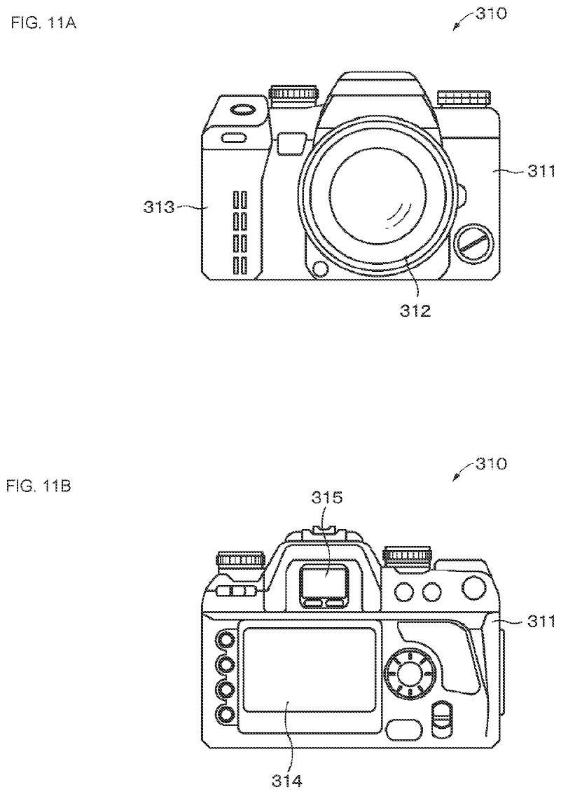

FIG. 11A is a front view illustrating an example of an external appearance of a digital still camera 310. FIG. 11B is a rear view illustrating an example of an external appearance of the digital still camera 310. The digital still camera 310 is of a lens interchangeable single-lens reflex type, and includes an interchangeable imaging lens unit (interchangeable lens) 312 substantially at the center on a front surface of a camera main body (camera body) 311, and a grip 313 to be held by a photographer on a front left side.

A monitor 314 is provided at a position shifted to the left side from the center of a rear surface of the camera main body 311. An electronic viewfinder (eyepiece window) 315 is provided above the monitor 314. By looking through the electronic viewfinder 315, the photographer can visually confirm a light image of a subject guided from the imaging lens unit 312 and determine a picture composition. As the electronic viewfinder 315, any display device 10 according to one of the above-described embodiments and modification examples thereof may be used.

### Specific Example 2

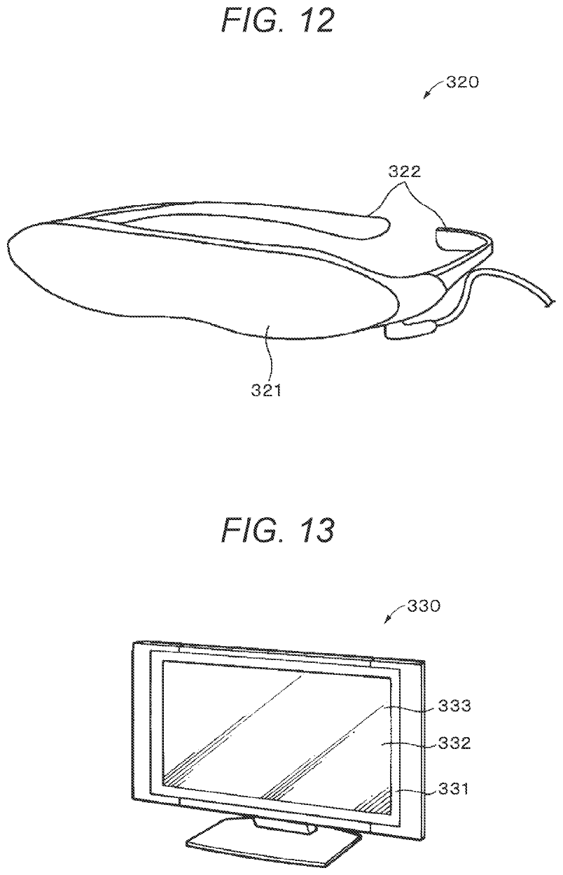

FIG. 12 is a perspective view illustrating an example of an external appearance of a head mounted display 320. The head mounted display 320 includes, for example, ear hooking portions 322 to be worn on the head of the user on both sides of a glass-shaped display unit 321. As the display unit 321, any display device 10 according to one of the above-described embodiments and modification examples thereof may be used.

### Specific Example 3

FIG. 13 is a perspective view illustrating an example of an external appearance of a television device 330. The television device 330 includes, for example, a video display screen unit 331 including a front panel 332 and a filter glass 333, and the video display screen unit 331 includes any display device 10 according to one of the above-described embodiments and modifications thereof.

Although the embodiments of the present disclosure, the modifications thereof, and the examples of the manufacturing method thereof have been specifically described above, the present disclosure is not limited to the above-described embodiments, modifications thereof, and examples of the manufacturing method thereof, and various modifications based on the technical idea of the present disclosure can be made.

For example, the configurations, methods, steps, shapes, materials, numerical values, and the like mentioned in the above-described embodiments, modifications thereof, and examples of the manufacturing method thereof are merely examples, and different configurations, methods, steps, shapes, materials, numerical values, and the like may be used as necessary.

Furthermore, the configurations, methods, steps, shapes, materials, numerical values, and the like described in the above-described embodiments, modifications thereof, and examples of the manufacturing method thereof can be combined with each other without departing from the gist of the present disclosure.

The materials exemplified in the above-described embodiments can be used alone or in combination of two or more unless otherwise specified.

Note that the contents of the present disclosure are not to be construed as being limited by the effects exemplified in the present disclosure.

The present disclosure may have the following configurations.

(1)

A display device including:
a light emitting element substrate provided with a light emitting element; and
an organic layer provided on the light emitting element substrate and having a color filter, in which
there is a display area determined as a region where light generated by the light emitting element is emitted,
the color filter includes a first color filter on which light generated by the light emitting element is incident,
in a case where an inward-outward direction is determined along a plane direction of the display area,
a non-formation portion of the organic layer is present outside the first color filter, and
in a case where a direction from the organic layer toward the light emitting element substrate along a thickness direction of the organic layer is defined as a downward direction,
a light shielding layer is at least partially formed immediately below the non-formation portion.
   (2)

The display device according to (1) described above, in which
the color filter includes a second color filter formed outside of the first color filter,
at least one groove portion that divides the organic layer in an inward-outward direction is provided in a formation region of the second color filter,
a seal portion that covers at least a part of the organic layer is provided,
the seal portion fills the groove portion,
the groove portion forms at least a part of the non-formation portion, and
the light shielding layer is formed at least in an immediately lower part that is defined as a portion immediately below the groove portion, in a portion immediately below the non-formation portion.
   (3)

The display device according to (2) described above, in which
the groove portion is formed at a position outside the display area.
   (4)

The display device according to (2) or (3) described above, in which
the second color filter has a light shielding property.
   (5)

The display device according to any one of (2) to (4) described above, in which
the second color filter has a single color filter, or a laminated structure of a plurality of filters individually corresponding to a plurality of different color types.
   (6)

The display device according to any one of (2) to (5) described above, in which
a plurality of the groove portions is formed, and
a plurality of the groove portions divides the organic layer into a plurality of portions in an inward-outward direction.
   (7)

The display device according to (6) described above, in which
in the light shielding layer, a plurality of the immediately lower parts is determined corresponding to a plurality of the groove portions, and
the light shielding layer traverses at least two of the immediately lower parts.
   (8)

The display device according to (6) described above, in which
a plurality of the light shielding layers is provided, and
each of the light shielding layers is provided at least in each of the immediately lower parts corresponding to a plurality of the groove portions.
   (9)

The display device according to any one of (2) to (8) described above, in which
a bottom surface of the groove portion is located on a lower side from the organic layer.
   (10)

The display device according to any one of (2) to (9) described above, in which
an alignment mark is formed at a predetermined position of the groove portion.
   (11)

The display device according to any one of (2) to (10) described above, in which
an inorganic layer containing an inorganic material is formed between the organic layer and the seal portion and between the groove portion and the seal portion.
   (12)

The display device according to any one of (2) to (11) described above, in which
the organic layer includes an organic planarization layer containing an organic material on a lower surface side of the color filter.
   (13)

The display device according to any one of (1) to (12) described above, in which
the light emitting element substrate includes a drive substrate having a structure in which an electric circuit is provided on a substrate, and
the light shielding layer has a lower light reflectance than the drive substrate.
   (14)

The display device according to any one of (1) to (13) described above, in which
a seal portion that covers at least a part of the organic layer is provided,
there is a filling layer formed in the organic layer so as to cover at least the display area, and
the filling layer also serves as the seal portion.
   (15)

An electronic device, in which
the display device according to any one of (1) to (14) described above is used.

### REFERENCE SIGNS LIST

10 Display device
10A Display area
10B Outer area
12 Drive substrate
12A Substrate
12B Insulating layer
13 First electrode
14 Organic light emitting layer
15 Second electrode
16 Protective layer
17 Color filter
18 Organic planarization layer
19 First color filter
20 Second color filter
21 Lens
26 Light shielding layer
27 Groove portion
28 Filling layer
29 Seal portion
30 Counter substrate
31 Auxiliary electrode
32 Alignment mark
33 Immediately lower part
34 Pad portion
35 Inorganic layer
36 Non-formation portion
100 Light emitting element substrate
101 Sub-pixel
102 Organic layer

1. A display device comprising:
a light emitting element substrate provided with a light emitting element; and
an organic layer provided on the light emitting element substrate and having a color filter, wherein
there is a display area determined as a region where light generated by the light emitting element is emitted,
the color filter includes a first color filter on which light generated by the light emitting element is incident,
in a case where an inward-outward direction is determined along a plane direction of the display area,
a non-formation portion of the organic layer is present outside the first color filter, and
in a case where a direction from the organic layer toward the light emitting element substrate along a thickness direction of the organic layer is defined as a downward direction,
a light shielding layer is at least partially formed immediately below the non-formation portion.

2. The display device according to claim 1, wherein
the color filter includes a second color filter formed outside of the first color filter,
at least one groove portion that divides the organic layer in an inward-outward direction is provided in a formation region of the second color filter,
a seal portion that covers at least a part of the organic layer is provided,
the seal portion fills the groove portion,
the groove portion forms at least a part of the non-formation portion, and
the light shielding layer is formed at least in an immediately lower part that is defined as a portion immediately below the groove portion, in a portion immediately below the non-formation portion.

3. The display device according to claim 2, wherein
the groove portion is formed at a position outside the display area.

4. The display device according to claim 2, wherein
the second color filter has a light shielding property.

5. The display device according to claim 2, wherein
the second color filter has a single color filter, or a laminated structure of a plurality of filters individually corresponding to a plurality of different color types.

6. The display device according to claim 2, wherein
a plurality of the groove portions is formed, and
a plurality of the groove portions divides the organic layer into a plurality of portions in an inward-outward direction.

7. The display device according to claim 6, wherein
in the light shielding layer, a plurality of the immediately lower parts is determined corresponding to a plurality of the groove portions, and
the light shielding layer traverses at least two of the immediately lower parts.

8. The display device according to claim 6, wherein
a plurality of the light shielding layers is provided, and
each of the light shielding layers is provided at least in each of the immediately lower parts corresponding to a plurality of the groove portions.

9. The display device according to claim 2, wherein
a bottom surface of the groove portion is located on a lower side from the organic layer.

10. The display device according to claim 2, wherein
an alignment mark is formed at a predetermined position of the groove portion.

11. The display device according to claim 2, wherein
an inorganic layer containing an inorganic material is formed between the organic layer and the seal portion and between the groove portion and the seal portion.

12. The display device according to claim 1, wherein
the organic layer includes an organic planarization layer containing an organic material on a lower surface side of the color filter.

13. The display device according to claim 1, wherein
the light emitting element substrate includes a drive substrate having a structure in which an electric circuit is provided on a substrate, and
the light shielding layer has a lower light reflectance than the drive substrate.

14. The display device according to claim 1, wherein
a seal portion that covers at least a part of the organic layer is provided,
there is a filling layer formed in the organic layer so as to cover at least the display area, and
the filling layer also serves as the seal portion.

15. An electronic device, wherein
the display device according to claim 1 is used.
